(19) United States
(12) Patent Application Publication
(10) Pub. No.: US 2005/0253172 A1
(43) Pub. Date: Nov. 17, 2005

(54) Charge carrier flow apparatus and methods

(76) Inventor: Christopher Croft Jones, Winchester, MA (US)

Correspondence Address: KIRKPATRICK & LOCKHART NICHOLSON GRAHAM LLP;(FORMERLY KIRKPATRICK & LOCKHART LLP), 75 STATE STREET, BOSTON, MA, 02109-1808, US

(21) Appl. No.: 11/119,379

(22) Filed: Apr. 29, 2005

Related U.S. Application Data
(60) Provisional application No. 60/566,695, filed on May 1, 2004.
(60) Provisional application No. 60/573,164, filed on May 22, 2004.
(60) Provisional application No. 60/616,654, filed on Oct. 6, 2004.

(51) Int. Cl. H01L 23/58; H01L 29/744

(52) U.S. Cl. 257/212

(57) ABSTRACT

In one aspect, the invention relates to a device for transporting charge carriers. The device includes two conducting regions connected by a nanochannel adapted for transporting a charge carrier. The nanochannel has a cross-sectional dimension less than or equal to the mean free path (MFP) of the charge carrier. Electrical devices including patterned and interconnected conducting layers are described herein whose interconnections are of nanoscale size and whose properties are determined by the shape and size of the interconnections.

### CROSS REFERENCE TO RELATED APPLICATIONS

This application claims the benefit of the following U.S. Provisional Applications, namely, U.S. Provisional Application No. 60/566,695 filed on May 1, 2004, U.S. Provisional Application No. 60/573,164 filed on May 22, 2004, and U.S. Provisional Application No. 60/616,654 filed on Oct. 6, 2004. The disclosures of which are herein incorporated by reference in their entirety.

### FIELD OF THE INVENTION

The invention relates generally to devices and methods for controlling the movement of charge carriers and in particular, devices and methods of altering electrical properties by applying a potential across a nanochannel.

### BACKGROUND OF THE INVENTION

The number of devices that operate based upon voltage changes and the propagation of electric current is staggering. Only more staggering is the extent that modern day consumers and industrial users depend on such devices. Integrated circuits, communication devices, computers, detectors and others contribute to the almost infinite variety of devices that function because of the transport and separation of charge carriers. However, when designed, engineers typically only consider electrical interactions at the current or voltage level.

Generally, a statistical process is used to calculate current flow and charge distribution. As a result, at that statistical level, the interaction (or collision) of electrons with each other is the dominate effect. Thus, current analysis for various devices is principally concerned with electron-electron interactions without regard for other types of individual electron behaviors.

Because of the need for faster and more efficient electronic circuit elements, new paradigms are necessary to advance the state of the electrical arts. Accordingly, new frontiers of electron interactions and the associated classes of devices that follow from those interactions warrant further investigation.

### SUMMARY OF THE INVENTION

The invention relates in part to current and voltage devices that function via effects analogous to molecular flow, thermal molecular pressure, transpiration, accommodation, and other conductor size and geometry specific charge transport principles. In one aspect, the new devices and methods disclosed herein exhibit behaviors based, in part, on conductor geometry and sizing. At a fundamental level, the invention relates to conducting and insulating regions, either within the same layer, on separate layers, or that are layer independent, whose connection to each other are by means of channels or apertures. The dimensions of the relevant conducting channels and apertures are of the order of, or smaller than the mean free path of the charge carriers in the conductors. One advantage of the invention is the fact that only conductor and insulator elements are required to fabricate certain embodiments.

Although, the invention relates to different aspects and embodiments, it is understood that the different aspects and embodiments disclosed herein can be integrated together as a whole or in part, as appropriate. Thus, each embodiment disclosed herein can be incorporated in each of the aspects to varying degrees as appropriate for a given implementation.

In one aspect, the invention relates to a device for transporting charge carriers. The device includes two conducting regions connected by a nanochannel adapted for transporting a charge carrier. The nanochannel has a cross-sectional dimension less than or equal to the mean free path (MFP) of the charge carrier.

The conducting regions include a metal layer disposed substantially adjacent an insulating layer in one embodiment. In another embodiment, the conducting regions and the nanochannel are disposed substantially within a unitary metal layer. A length of the nanochannel is greater than, approximately equal to or less than the mean free path (MFP) of the charge carrier in one embodiment. Nanochannels can be longer than the MFP of a charge carrier in various embodiments. In addition, in one embodiment, the nanochannel is adapted for use as a via that connects two or more metal layers, the metal layers sandwiching a portion of the at least one insulating layer.

In one embodiment, the device further includes another nanochannel such that one nanochannel connects the conducting regions on the metal layer disposed substantially adjacent the insulating layer while the other nanochannel is adapted for use as a via. The via allows charge carrier transport between the first metal layer and a second metal layer having a third conducting region. The via is approximately equal to or less than the mean free path (MFP) of the charge carriers. In one embodiment, the device is fabricated using a nanoscale semiconductor lithography process. In one embodiment, the nanochannel cross-sectional area can be non-uniform along its length. In one embodiment, the via is an aperture or channel used for interconnection of conductors on different sides or layers of an electronic device. Multiple nanochannels are used in various device embodiments to improve signal detection resulting from charge carrier flow.

Furthermore, in one embodiment, one conducting region of the device is in electrical communication with a Y junction. The Y junction includes one nanochannel in electrical communication with the one conducting region, two branches, and a base connecting the branches, wherein selection of one of the branches by a charge carrier entering the base changes in response to application of an electric field.

In another aspect, the invention relates to a device adapted for transporting a charge carrier in response to a potential change. The device includes an insulating layer, a first conducting layer, a second conducting layer and a nanochannel. The nanochannel has a cross-sectional dimension less than or equal to the mean free path (MFP) of the charge carrier. The nanochannel connects a portion of the first and second conducting layers. Additionally, a portion of the insulating layer is sandwiched between the first and second conducting layers.

In one embodiment, the first conducting layer has an associated first potential (V₁) and first temperature (T₁) and the second conducting layer has an associated second potential (V₂) and second temperature (T₂). The potentials and temperatures are related such that

$$\frac{{V}_{1}}{{V}_{2}} ≅ \sqrt{\frac{{T}_{1}}{{T}_{2}}} .$$

Alternatively, in another embodiment, the potentials and temperatures are related such that V₁−V₂≅½*(T₁−T₂)/T₂)*V₂. In another embodiment, the device is adapted for use as an infrared detector, a heat dissipating device, an electromagnetic energy detector and/or combinations thereof. The charge carrier is an electron or a hole. The potential can be a thermal potential, an electrical or other charge affecting potential.

In yet another aspect, the invention relates to a method of regulating charge carrier flow. The method includes the steps of restricting a nanochannel dimension such that the dimension is less than or equal to the mean free path (MFP) of the charge carrier and transporting a charge carrier between at least two conductive regions by varying a potential between the two regions.

In one embodiment, the potential is a thermal potential or an electrical potential. In other embodiments, the nanochannel dimension ranges from about 2 nanometers to about 40 nanometers. While in other embodiments, a nanochannel dimension ranges from about 40 nanometers to about 80 nanometers. In one embodiment, a nanochannel dimension is less than or about equal to the MFP. The charge carrier flow has an associated current, the current adapted for detecting changes in the potential in one embodiment.

In yet another aspect, the invention relates to a circuit adapted for transporting a charge carrier in response to a potential change. The circuit includes two conducting regions connected by a channel adapted for transporting a charge carrier. The channel has a cross-sectional dimension less than or equal to the mean free path (MFP) of the charge carrier. In one embodiment, the channel is a nanochannel.

The details of one or more embodiments of the invention are set forth in the accompanying drawings and the description below. Other features, objects, and advantages of the invention will be apparent from the description, drawings and examples, and from the claims.

### BRIEF DESCRIPTION OF THE DRAWINGS

Reference to the figures herein is intended to provide a better understanding of the methods and apparatus of the invention but are not intended to limit the scope of the invention to the specifically depicted embodiments. The drawings are not necessarily to scale, emphasis instead being placed upon illustrating the principles of the invention. Like reference characters in the respective figures typically indicate corresponding parts.

FIG. 1 is a schematic diagram of a charge transport device according to an illustrative embodiment of the invention;

FIG. 2 is a schematic diagram of a charge transport device formed in a single layer according to an illustrative embodiment of the invention;

FIG. 3 is a schematic diagram of a multi-layer charge transport device according to an illustrative embodiment of the invention;

FIG. 4 is a schematic diagram of a charge transport device adapted for asymmetric charge carrier flow according to an illustrative embodiment of the invention;

FIG. 5 is a schematic diagram of another charge transport device adapted for asymmetric charge carrier flow according to an illustrative embodiment of the invention;

FIG. 6 is a schematic diagram of a device adapted for selectively directing charge carriers according to an illustrative embodiment of the invention;

FIG. 7 is a perspective view of a detector device according to an illustrative embodiment of the invention; and

FIG. 8 is a perspective of a flow diagram depicting some of steps for fabricating the device of FIG. 7 according to an illustrative embodiment of the invention.

### DETAILED DESCRIPTION

The following description refers to the accompanying drawings that illustrate certain embodiments of the present invention. Other embodiments are possible and modifications may be made to the embodiments without departing from the spirit and scope of the invention. Therefore, the following detailed description is not meant to limit the present invention. Rather, the scope of the present invention is defined by the appended claims.

It should be understood that the order of the steps of the methods of the invention is immaterial so long as the invention remains operable. Moreover, two or more steps may be conducted simultaneously unless otherwise specified. In addition, it should be understood that the terms “a,” “an,” and “the” mean “one or more,” unless expressly specified otherwise.

Prior to describing different aspects and embodiments of the invention in detail, an introduction to some of the characteristic terminology used herein may prove informative. However, the scope of the terms discussed herein is not intended to be limiting, but rather to clarify their usage and incorporate the broadest meaning of the terms as known to those of ordinary skill in the art. Specifically, some of the terms that are summarized herein include mean free path, nanochannel, nanoaperture, and nanobarrier.

The term mean free path (hereafter, MFP) of a charge carrier describes the mean distance that a charge carrier (such as an electron or hole) travels before encountering the influence of another charge carrier.

The term nanochannel describes a conducting channel, which connects two or more conducting regions, a conducting region and another nanochannel, or two or more nanochannels. Typically, a nanochannel further includes at least one position along the channel where charge flow constricts to a cross-sectional dimension that is of the order of, approximately equal to, or less than the MFP of the charge carriers in the conductor. The specific shape of a nanochannel contributes to its electrical charge transport properties. A nanochannel can include a conductive material or an appropriately doped or undoped semiconductor material.

The term nanoaperture describes a connection between conducting regions that is a subset or type of nanochannel. A nanoaperture has a length that is of the same order as, or smaller than the MFP of a charge carrier in the conductor. A nanoaperture can include a conductive material or an appropriately doped or undoped semiconductor material.

The term nanobarrier refers to a gap between conducting regions having a thickness that is of the order of, or smaller than the MFP of the charge carriers in a conductor. A nanobarrier can be substantially empty or can include an insulating or appropriately doped or undoped semiconductor material. However, in various embodiments different arrangements of nanochannels, nanoapertures, and nanobarriers can include conductor portions, insulator portions, and substantially empty portions as appropriate.

The purpose and operating principles of a particular device embodiment determine the nanochannel length. For the case of a transpiration implementation, the ‘electron gas’ in each of the conducting regions establishes its own kinetic equilibrium independently of the other region. In such an embodiment, this kinetic equilibrium occurs in spite of the existence of the connecting nanochannels, which are essentially invisible as thermal paths because of their small cross-section. Nevertheless, individual electrons can pass through the nanochannels and thus form the basis for transpiration devices. In this type of implementation, the length should be as small as possible, subject to electron tunneling constraints. However, asymmetric flow devices depend on interactions between the charge carriers within the boundaries of a longer channel. As a result, the length of the nanochannel is greater than, approximately equal to or less than the mean free path (MFP) of the charge carrier. Yet, the cross-section dimension remains equal to or less than the MFP of the charge carrier.

Generally, in other electrical devices known in the art, the designs rely on interactions between individual charge carriers. In contrast, the electrical responsiveness, circuits, devices, and methods of the aspects of the invention substantially derive from charge carriers interacting with the boundaries of conducting and insulating structures. Thus, in part, the invention relates to devices incorporating combinations of nanoaperture, nanochannel and/or nanobarrier structures between conducting regions.

Furthermore, the invention relates to the design of structures whose shape, size, and conducting material layout provide the capability to detect, rectify, control, and/or amplify electronic signals. Some of these devices and their component elements are sized relative to the mean free path of an electron or other charge carrier to produce electron-boundary interactions.

The concept of a mean free path (MFP) is relevant to many of the aspects and embodiments of the invention described herein. The MFPs for electrons in metals are in the range of several hundred angstroms. For example, the mean free path for an electron at room temperature in a typical metal is about 40 nanometers (400 angstroms). The electrons and holes in semiconductors have their own characteristic MFP length ranges. For circuit designs at the micron (10,000 angstrom) range and above, electron to electron collisions dominate over interactions with the boundary in calculation of charge transport.

However, as the invention relates to structures fabricated in the nanotechnology domain, wherein structure sizes are below 1,000 angstroms (e.g., the 90 nm node), other effects have been discovered. In particular, if conductor dimensions, in relation to an electron (or hole) MFP are no longer negligible, other nanoscale electrical phenomena become significant to device design and functionality. The devices and methods disclosed operate solely or in part because of these MFP sized electrical boundaries. In general, the structures of different aspects and embodiments include one or more regions that connect to one or more regions via an aperture or a channel. In different embodiments, the channel can include any conducting connection between two regions or volumes, such as for an example a tube, a groove, a closed connector, an open connector, a cone, and/or any appropriately sized intervening regular or irregular region between conductors and combinations thereof.

To further advance the theory of charged particle interactions, the Applicant has discovered that different theoretical perspectives can be fused to suggest novel devices, methods, and circuit elements. In particular, the Applicant combines ideal gas concepts, electron-conductor theory, quantum mechanical principles, and thermodynamic principles to develop device structures and explanations for their operation. Therefore, prior to considering specific aspects and embodiments, it will be useful to explore some of the underlying principles used in their designs.

The statistical behavior of the electron gas in a conducting material can be related to that of an ideal gas. In turn, the gas is analyzed by considering the coordinates of position (q) and momentum (p) for the molecules in phase space. The phase space being subdivided into cells of size ΔpΔq. The cells have the dimension of action (e.g., joule-sec). Quantum Mechanics teaches us that the limiting resolution of a cell is given by Max Planck's quantum of action, h, which has the value 6.62 e-34 joule-sec.

Degeneracy refers to the degree to which the cells in phase space are occupied by more than one particle. Occupancy is sparse for the ideal gas where only about one of every 30,000 phase cells is occupied. It is unlikely, then, that multiple occupancy would occur, and thus the ideal gas is, in all but a few unusual cases near absolute zero, nondegenerate.

Such is not the case for the electron gas, where several thousand electron states may occupy the same cell in phase space. Degeneracy, together with other divergent properties, does not preclude prediction of the behavior of the electron gas based on its analogy with the ideal gas but there are differences, some of which are discussed later in this specification. However, given this fundamental difference between electron gas and ideal gas behavior, successfully integrating aspects of these different approaches is challenging.

Some attributes of electron conductivity in metals have been successfully characterized using methods taken from the Kinetic Theory of Gases. However, the lack of fabrication technology in the deep submicron domain has precluded the development of nanoscale devices. When individual charge carriers that comprise the electron ‘gas’ in metals and semiconductors are constrained by conductors having specifically sized dimensions in the range of charge carriers' MFP new phenomena are present. Thus, since the MFPs considered in the Kinetic Theory of Gases are in the low micron range, conductors at that size scale would fail to exhibit the boundary interaction behavior that occurs when the MFP is a few hundred angstroms.

However, additional design ideas can be ascertained by considering other non-electron gas related experimentation. Others have studied the process of thermal transpiration also referred to as thermal molecular pressure. In one exemplary experiment relating to this phenomenon, two chambers containing a gas are separated by a barrier containing an aperture having small dimensions. If one of the chambers is held at a temperature higher than the other, its equilibrium pressure will also be higher than that of the other, according to the following formula,
P₁/P₂=SQRT(T₁/T₂), (Eq. 1)
where T=temperature and, P=pressure
   For small differences in temperatures, this expression can be simplified to,
   P₁−P₂=½*(T₁−T₂)/T₂)*P₂. (Eq. 2)

In another historic thermal transpiration experiment, a ceramic ball with very small pores is connected to a tube, the end of which is submerged in a glass of water. When a heating element inside the ball is energized, the air inside the ball is warmer than the air outside, thus causing air to pass from the colder outside through the porous wall into the ball. Continuous bubbling occurs from the end of the tube immersed in water, as long as the heating element is energized. In addition, rarified gases were studied so that the mean free path of the gas particles would be large with regard to the size of the pores. The resulting gas flow between volumes was referred to as molecular effusion.

Accordingly, although the quantum mechanical nature of the electron gas makes the experiments discussed above seem inapplicable to electric device development, aspects of the invention extend some of these concepts to formulate new designs. Thus, for some of the embodiments disclosed herein, when one or more nanoapertures or nanochannels connect two regions, each region appears to be oblivious to the aperture/channel and consequently attempts to arrive at a thermal equilibrium condition independent of the existence of the aperture/channel. In addition, Eq. 1 and Eq. 2 can be extended to electrical phenomena as discussed in more detail below.

In modeling the case of a gas passing through a tube from one region to another, other phenomena were studied. Although, these properties may differ from processes involving an electron gas additional electric device design features may be enhanced by considering an additional phenomenon.

The relevant phenomenon concerns the scattering of the gas particles after impact with a surface. It remained unclear as to whether the gas particle scattering would be specular (mirror like) and/or diffuse Lambertian. This property, i.e., scattering from a boundary surface, is important in the design of nanochannel devices, and it is reasonable to assume that other mechanisms may affect the scattering of electrons from a conductor boundary. Some researchers suggest that specular scattering may be expected in crystalline structures. Thus, scattering of electrons may be more specular. As specular scattering and boundary collisions and reflections are possible at the nanoscale level various asymmetric channel configurations that “funnel” electrons in a specific direction are possible. Lambertian and specular scattering may be selected for a given charge carrier device or device portion by introducing different conductor and insulator configurations.

Further, at the submicron level at which some features of the devices described herein operate, quantum mechanical effects become important. From quantum mechanical principles, an electron moving with a momentum p (and energy p²/2mₑ where mₑ=the mass of the electron, 9.0 e-31 kg) acts as an oscillator of fundamental wavelength h/p (where h=Planck's quantum of action, 6.62 e⁻³⁴ joule-sec).

The electron gas explores the boundaries of its enclosure and in equilibrium distributes the energy of its individual electrons among a set of available energy states (eigenstates) as determined by the material, shape, and size of the enclosure so as to maximize its entropy. Further quantum mechanical analysis reveals that, from a viewpoint, for a region containing an electron gas, it is the collection of eigenstates that determines its properties without concern for which state goes with a particular electron. Yet, when realization of a specific event is required, the wave function must collapse probabilistically to an occurrence of that event (e.g., detection of an electron.)

For all but the simplest cases, exact quantum mechanical solutions to real life systems are prohibitively complicated. The momentum of all of the individual electrons (and their fundamental wavelengths) together with the properties and boundary conditions of the region within which they reside, determine a wavefunction from which the distribution of states must be derived. The examples below then, where quantum mechanical considerations are appropriate derive from qualitative analysis combined with mathematical support.

The average electron velocity, assuming a Maxwellian distribution, is given by,
v=1/(2mₑ/kT)^{1/2}
where mₑ=mass of the electron, k=Boltzmann's constant, and T=the absolute temperature. For a temperature of 273 degrees absolute, the mean velocity is 8.1 e4 m/s, with a resulting deBroglie wavelength of 9 nanometers. Thus, given an electron's wave nature, one aspect of the invention relates to waveguide-like nanoaperture and nanochannel structures. In addition, one embodiment relates to channels having dimensions sized from about 1 nm to about 100 nm.

These waveguide structures can select, reject, amplify, attenuate, and/or otherwise control the distribution of eigenstates between or solely within conducting regions, thereby controlling the transport of electronic currents within the regions. This can include continuous patterns of nanochannels within and on the boundaries of conducting surfaces to shape the composition of eigenstates. In contrast, as stated above, the operation of the devices described in this invention is at least partially determined by the shape and size of the nanoscale pattern bridging one or more larger conducting regions.

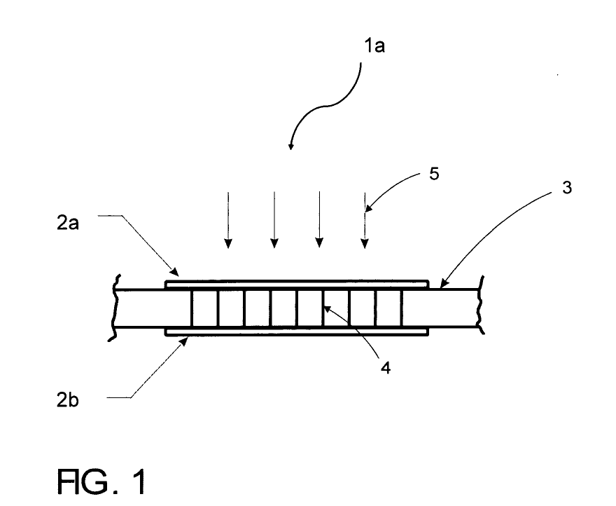

FIG. 1 depicts a charge carrier transport device 1a. The exemplary device 1a shown can operate as an infrared (IR) detector or as an element in a larger IR detector. FIG. 1 shows two conducting layers 2a and 2b that are separated by an insulating layer 3. In one embodiment, the insulating layer 3 functions as a nanobarrier.

Additionally, the two layers 2a, 2b are in electrical communication with each other. Specifically, they are connected by a nanochannel and/or a nanoaperture 4. The nanochannel/nanoaperture 4 penetrates a portion of the insulating layer 3. Alternatively, a plurality of nanochannels or nanoapertures can be used in some embodiments. The insulating layer 3 in combination with the nanochannel/nanoaperture 4 regulate and direct the flow of the charge carriers.

The thickness of the conducting layers 2a, 2b can vary over a wide range. In one device embodiment, the conductor layer thickness is from about 100 to about 200 nanometers thick. The thickness of the insulator layer 3 should be as thin as possible without incurring tunneling or breakdown effects. Any insulator thicknesses that satisfy this condition are suitable for use in different embodiments. In particular, the value of the insulator is from about 5 nanometers to about 20 nanometers. More particularly, the range of the insulator is from about 10 nanometers to about 15 nanometers in other embodiments.

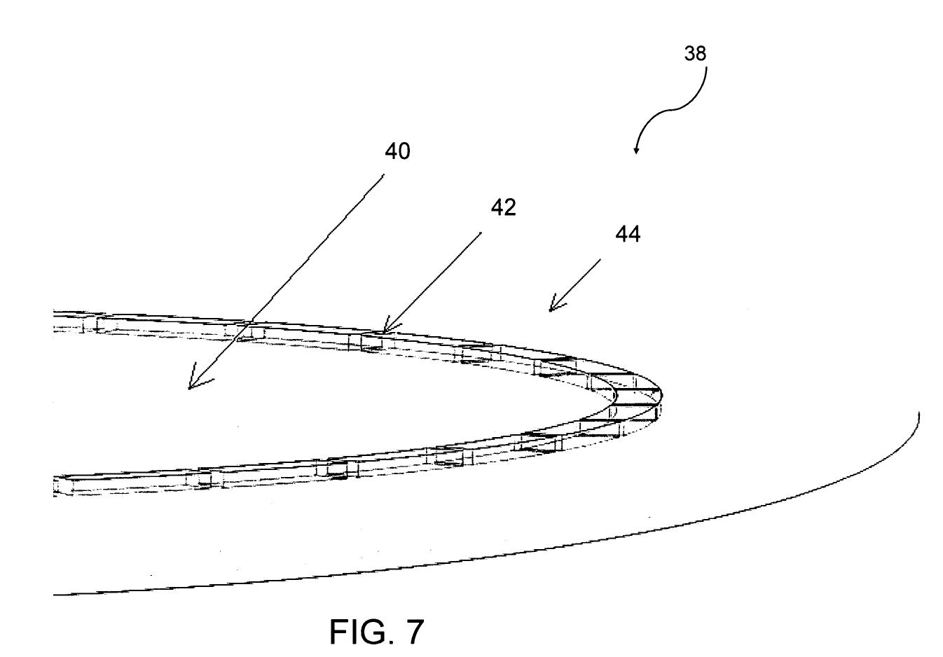

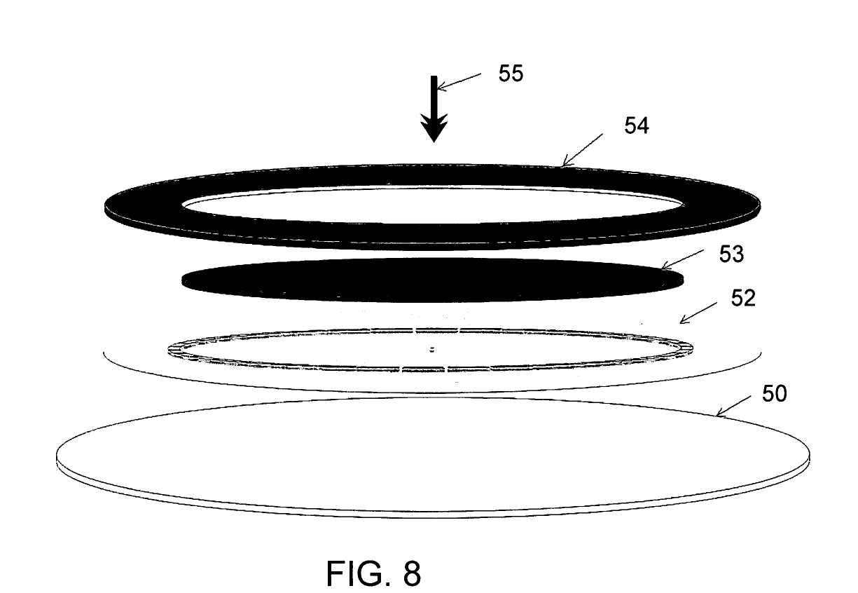

Embodiments using conductors and insulators arranged in alternating layers or substrate portions make electrons available or unavailable for transport. Electron or hole transport is achieved through nanobarriers channels, vias, or apertures in response to some physical effect or potential difference. Thus, various responsive circuit elements and detectors can be fabricated. Thus, as mentioned above, the device 1a can be used as an IR detector. A single layer detector embodiment, such as described below with regard to FIGS. 7 and 8 is also within the scope of the invention.

In FIG. 1, the IR energy 5 impinging on the upper layer 2a causes its temperature to rise in accordance with the thermal molecular flow principle described above. Consequently, electrons are drawn from layer 2b through the nanochannel/nanoaperture(s) 4 in accordance with transpirational flow and potential difference principles in combination with treating the electrons as a Debye gas. However, the invention is not limited to any particular theory or mechanism.

Each of the layers, if isolated and at different kinetic energies (temperatures; T_{1 and T}₂) will establish a separate thermodynamic equilibrium. If a traditional thermal conducting path (not a nanochannel/nanoaperature) is established between the hot and cold layers, charge carriers from the hot layer will travel to the cold layer in accordance with conventional thermodynamics. However, if instead of a traditional thermal conductor, a circuit is formed by adding one or more nanochannels to connect the layers, although counterintuitive, the resultant circuit causes charge carrier flow in the opposite direction such that electrons flow from the cold layer to the hot layer (transpirational flow). Since the nanochannel size is much smaller than the MFP of the electrons, their connection to the layers has negligible influence on the thermodynamic equilibrium of the layers. This follows because the electron to electron and electron to boundary collisions are the dominant thermal effects in the layers.

However, individual electrons can find the nanochannels and slip through. As the cold layer has a greater electron density and lower energy electrons, the cold layer electrons pass through the nanochannels more often and establish a new detectable equilibrium condition. Alternatively, a continuous current flow is possible between the hot and cold layers, if a closed circuit path is available as described above with regard to FIG. 1.

Thus, the electrons flow from layer 2b to layer 2a through the nanochannel/nanoaperture(s) 4 in accordance with the following equation:
V₁/V₂=SQRT(T₁/T₂), (Eq. 3)
where T=temperature and, V=voltage
   For small differences in temperatures, the expression becomes,
   V₁−V₂=½*(T₁−T₂)/T₂)*V₂. (Eq. 4)
   For example, if (T₁−T₂)=0.1 deg C., T₂=273 deg C., and V₂=1 volt, then,
   V₁−V₂=183 microvolts.

Therefore, a voltmeter or other measurement device in communication with the layers 2a, 2b would detect a potential difference in response to the radiation. Alternatively, introducing a controlled potential difference across the layers 2a, 2b can affect the emission of IR. Multiple conducting and/or insulating layers may also be used to help tailor the response. In addition, an array comprising multiple instances of the device 1a shown in FIG. 1 can be formed on a metal, a semiconductor, or other suitable material to form a larger radiation detector. Additionally, the incident energy 5 need not be restricted to IR (infrared) but can be visible or any other portion of the electromagnetic spectrum, or for that matter, conducted thermal energy.

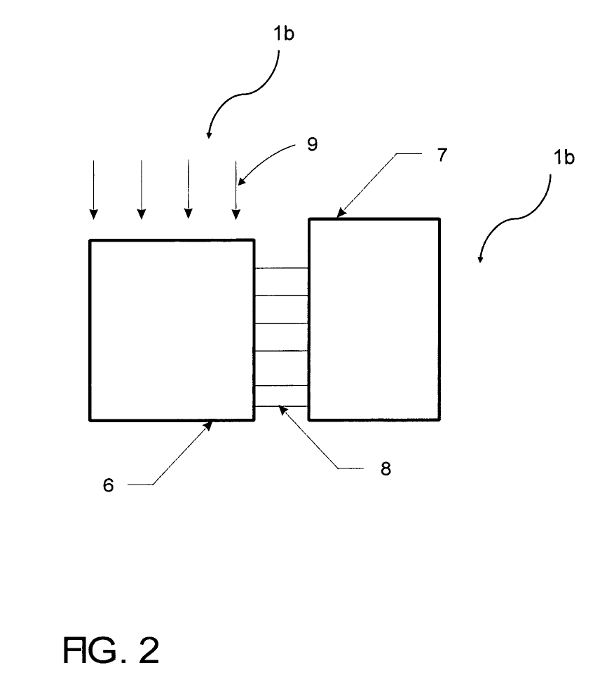

In turn, FIG. 2 illustrates an embodiment wherein the device 1a of FIG. 1 is fabricated on a single layer as opposed to two parallel layers. Integrating multiple conducting and insulating regions in one unitary semiconductor, metal or insulating layer/substrate provides further device size and manufacturing efficiencies. In FIG. 2, the device 1b includes a conducting region 6, which connects another conducting region 7 via a nanochannel or a nanoaperture 8. The conducting region 6 experiences a change in at least one physical or electrical parameter such as a potential, an energy level, or a temperature because of the impinging energy 9. In contrast, the electrical parameters in region 7 experience a correlated change in one or more physical or electrical parameters as a result of the charge carrier flow through the nanochannel or nanoaperture structures 8. Although not shown, one of the conductors is typically shielded with a suitable radiation shield or mask layer such as depicted in FIG. 8. Given the small size scale, precise placement is required to prevent simultaneous stimulation of both regions 6, 7 and undesirable radiation leakage elsewhere in a given device.

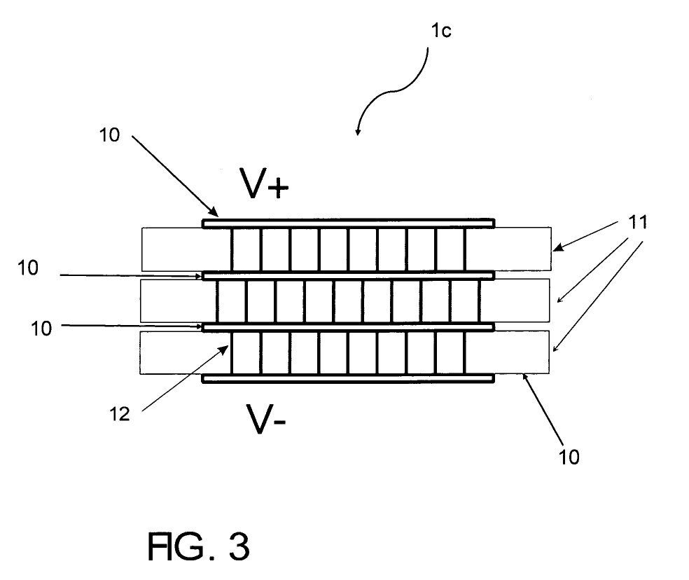

FIG. 3 illustrates the converse situation wherein a voltage is applied across a stack of conducting layers 10, isolated from each other by insulating layers 11, but connected by nanochannels and/or nanoapertures 12 through the insulation as described for the embodiment of FIG. 1. The electron flow principles described above dictates the equilibrium equation to be
T₁/T₂=(V₁/V₂)²
Thus by a creating a potential difference across the conductive regions 10 a temperature gradient is achieved. As a result, the device 1c of FIG. 3 allows for the fabrication of different classes of thermoelectric cooling and heating devices using the approaches described herein.

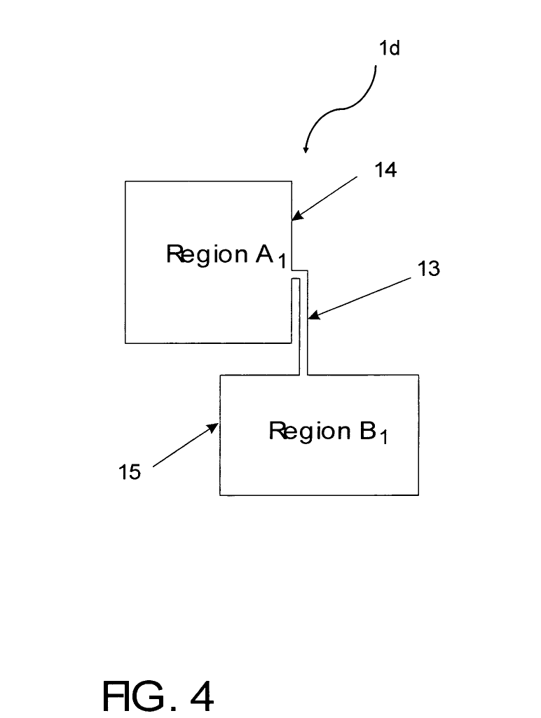

FIG. 4 depicts a nanochannel-based device embodiment 1d for causing charge transport in a preferred direction. The exact nature of this preference depends on the scattering characteristics of the charge carrier collisions with the boundary (e.g., specular, Lambertian, etc.) and as such is influenced by the manufacturing process. In one embodiment, Lambertian scattering describes charge carrier behavior in which the probability of scattering at a particular angle equals the cosine of that angle with reference to a line perpendicular to the surface at the point of impact, independent of the particle's arrival angle. For example, if the boundary scattering is diffuse or Lambertian, then a higher percentage of the energy entering the nanochannel 13 from region A₁ 14 would be reflected back into region A₁. This is in contrast to energy entering the nanochannel from region B₁ 15. This occurs because the preferred peak direction is perpendicular to the surface. A similar case can be made from the point of view of eigenstates, where excitation of different ends of the nanochannel produce a different result, analogous to the asymmetric result in sound exciting the two ends of a horn.

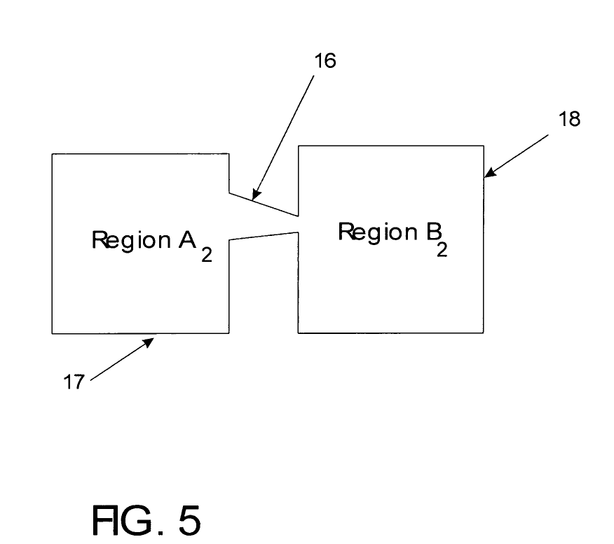

FIG. 5 illustrates another nanochannel 16 design resulting in asymmetric eigenstates in the nanochannel that can cause energy transport in a preferred direction between region A₂ 17 and region B₂ 18. As charge carriers “bounce” between the conductor boundaries, they tend to funnel towards one end of the conductor and into the nanochannel or nanoaperture. Alternatively, “posts” or bumpers can be formed within different conductor regions to further control charge carrier flow. The type of charge carrier scattering can also be tailored to further improve or retard charge flow in specific embodiments. Thus, using the approaches of FIGS. 1-5, different nanochannel conductor layouts are possible. These different layouts alter charge carrier flow, resulting in specific capacitive, inductive, and other properties in different embodiments.

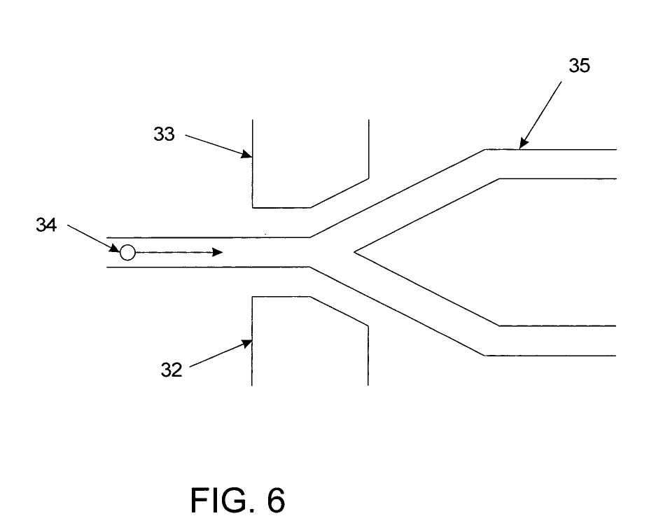

FIG. 6 illustrates a decision circuit embodiment. A potential applied between nodes 32 and 33 affects the decision of charge carrier 34 regarding which branch of the nanochannel Y junction 35 it chooses to enter. As is the case with modern day circuits, decision circuits can be chained together to form various nanoscale gates that can operate in response to Boolean logic commands. Thus, different embodiments of the invention can be used to extend Moore's law and achieve nanoscale binary processing.

FIG. 7 illustrates an exemplary detector embodiment 38. In particular, FIG. 7 illustrates a planar metallization layer adapted for the detection of electromagnetic energy. Although the overall geometry of the detector is substantially circular, other device geometries are possible. A collector 40 is present to collect incident electromagnetic radiation, such as for example IR. Although not shown, various other electrical connections can be in communication with the detector to measure currents, electric fields, and potential differences. The collector 40, which is exposed to incoming electromagnetic energy, is separated from the generator 44 by an array that includes a plurality of nanochannels 42. Thus, the two annular regions 40, 44 correspond to the conductors discussed above. In turn, the collector 40 and generator 44 are connected by a substantially circular nanochannel 42 array. When IR impinges on the collector, a signal is measured as a current flowing through the channels 42 or as a potential difference between the collector 40 and the generator 44.

FIG. 8 depicts an exemplary fabrication method for creating the device of FIG. 7. The method begins by providing a planar insulation layer 50. Next, a metallization layer 52 is deposited and patterned by electron beam lithography techniques (e.g., those provided by the IMPRIO 250 system by Molecular Imprints (1807-C West Braker Lane, Austin Tex.)) to form the nanochannels. Then a layer of high emissivity material 53 is deposited on the collector region of the detector layer 52 to maximize energy absorption. The high emissive material layer 53 is selected to be within the wavelength range of the incoming electromagnetic energy 55 to improve radiation absorption. Layer 54 shields the generator section of the metal layer 52 from the incoming electromagnetic energy 55 to improve the signal to noise ratio.

The structures disclosed herein can be fabricated using various lithographic techniques currently in use or development in the nation's research and industrial facilities. Designs for nanotechnology devices and their methods of manufacture have accelerated in recent years. Andideh and Myers, in U.S. Pat. No. 6,596,646, demonstrate how conventional lithographic techniques may be adapted to manufacture sub 100 nanometer semiconductor devices. In addition, the fabrication techniques disclosed in U.S. Pat. No. 6,586,965 to Knekes and U.S. Pat. No. 6,762,094 to Stasiak et al. are suitable for fabricating different aspects of the invention. Other recent advances (e.g., immersion lithography) indicate that manufacturing processes for the novel devices described herein are available to those of ordinary skill in the art. However, any suitable semiconductor fabrication device can be used.

One exemplary method provides a substrate and forms a mask thereon. In order to pattern the mask, one or more photoresist layers (or layer portions) are deposited on the mask. In turn, the photoresist layer(s) are patterned to remove or change the geometry/structure of the photoresist layer(s). The substrate and patterned photoresist layer are then selectively etched to impart a pattern to the substrate such as for example one or more conductor regions and a nanochannel. The substrate can be an insulator, a semiconductor or a metal in various embodiments. The etching can be accomplished by a plasma, gas or RIE method. In lieu of etching, in some embodiments the nanochannels can be laser etched. A conductive material such as a metal can be deposited within the conductor regions and/or the nanochannel to form the conductive path for the charge carriers. In some embodiments, different layers having nanochannels (or nanoapertures), conductor regions and insulator regions formed thereon are stacked together or otherwise electrically connected to form larger devices or circuits.

Since certain changes may be made in the foregoing disclosure without departing from the scope of the invention herein involved, it is intended that all matter contained in the above description and depicted in the accompanying drawings be construed in an illustrative and not a limiting sense.

The invention may be embodied in other specific forms without departing from the spirit or essential characteristics thereof. The foregoing embodiments contained in the above description and depicted in the accompanying drawings are therefore to be considered in all respects illustrative rather than limiting on the invention described herein. Scope of the invention is thus indicated by the appended claims rather than by the foregoing description, and all changes which come within the meaning and range of equivalency of the claims are intended to be embraced therein.

Each of the patent documents and scientific publications disclosed hereinabove is incorporated by reference herein for all purposes.

1. A device for transporting charge carriers, the device comprising:
two conducting regions connected by a nanochannel adapted for transporting a charge carrier,
wherein the nanochannel has a cross-sectional dimension less than or equal to the mean free path (MFP) of the charge carrier.

2. The device of claim 1 wherein the conducting regions comprise a metal layer disposed substantially adjacent an insulating layer.

3. The device of claim 2 wherein the conducting regions and the nanochannel are disposed substantially within a unitary metal layer.

4. The device of claim 1 wherein a length of the nanochannel is approximately equal to or less than the mean free path (MFP) of the charge carrier.

5. The device of claim 2 wherein the nanochannel is adapted for use as a via that connects two or more metal layers, the metal layers sandwiching a portion of the at least one insulating layer.

6. The device of claim 2 further comprising another nanochannel,
wherein one nanochannel connects the conducting regions on the metal layer disposed substantially adjacent the insulating layer while the other nanochannel is adapted for use as a via,
the via allowing charge carrier transport between the first metal layer and a second metal layer having a third conducting region.

7. The device of claim 6 wherein the length of the via is approximately equal to or less than the mean free path (MFP) of the charge carriers.

8. The device of claim 2 wherein the device is fabricated using a nanoscale semiconductor lithography process.

9. The device of claim 1 wherein the nanochannel cross-sectional area is non-uniform along its length.

10. The device of claim 1 wherein one conducting region is in electrical communication with a Y junction,
the Y junction comprising
one nanochannel in electrical communication with the one conducting region, two branches, and
a base connecting the branches,
wherein selection of one of the branches by a charge carrier entering the base changes in response to application of an electric field.

11. A device adapted for transporting a charge carrier in response to a potential change, the device comprising:
an insulating layer;
a first conducting layer;
a second conducting layer, wherein a portion of the insulating layer is sandwiched between the first and second conducting layers; and
a nanochannel having a cross-sectional dimension less than or equal to the mean free path (MFP) of the charge carrier and connecting the first and second conducting layers.

12. The device of claim 11, wherein the first conducting layer has an associated first potential (V₁) and first temperature (T₁) and the second conducting layer has an associated second potential (V₂) and second temperature (T₂).

13. The device of claim 12, wherein the potentials and temperatures are related such that
$$\frac{{V}_{1}}{{V}_{2}} ≅ \sqrt{\frac{{T}_{1}}{{T}_{2}}} .$$

14. The device of claim 12, wherein the potentials and temperatures are related such that V₁−V₂≅½*(T₁−T₂)/T₂)*V₂.

15. The device of claim 11, wherein the device is adapted for use as an infrared detector.

16. The device of claim 11, wherein the device is adapted for use as a heat dissipating device.

17. The device of claim 11, wherein the device is adapted for use as an electromagnetic energy detector.

18. The device of claim 11 wherein the charge carrier is an electron or a hole.

19. The device of claim 11 wherein the potential is a thermal potential or an electrical.

20. A method of regulating charge carrier flow, the method comprising the steps of
restricting a nanochannel dimension such that the dimension is less than or equal to the mean free path (MFP) of the charge carrier; and
transporting a charge carrier between at least two conductive regions by varying a potential between the two regions.

21. The method of claim 20 wherein the potential is a thermal potential or an electrical potential.

22. The method of claim 20 wherein the nanochannel dimension ranges from about 2 nanometers to about 40 nanometers.

23. The method of claim 20 wherein the charge carrier flow has an associated current, the current adapted for detecting changes in the potential.

24. A circuit adapted for transporting a charge carrier in response to a potential change, the circuit comprising:
two conducting regions connected by a channel adapted for transporting a charge carrier,
wherein the channel has a cross-sectional dimension less than or equal to the mean free path (MFP) of the charge carrier.
